(19) United States
(12) Patent Application Publication
(10) Pub. No.: US 2026/0164642 A1
(43) Pub. Date: Jun. 11, 2026

(54) SEMICONDUCTOR DEVICE

(71) Applicant: Samsung Electronics Co., Ltd., Suwon-si (KR)

(72) Inventors: Jun Hyeon BAE, Suwon-si (KR); Seung Min LEE, Suwon-si (KR); Jongho KIM, Suwon-si (KR); Sungwon YOO, Suwon-si (KR)

(21) Appl. No.: 19/201,107

(22) Filed: May 7, 2025

(30) Foreign Application Priority Data
Dec. 11, 2024 (KR) 10-2024-0183537

(51) Int. Cl. H10B 12/00

(52) U.S. Cl. CPC H10B 12/33; H10B 12/05

(57) ABSTRACT

A semiconductor device may include a semiconductor pattern on a substrate, a word line that extends in a first direction on the substrate, a gate insulating pattern on the substrate and between the semiconductor pattern and the word line, and a bit line extended in a second direction, on the semiconductor pattern. The word line may include a first pattern and a second pattern between the first pattern and the gate insulating pattern. The first pattern and the second pattern may include different materials from each other. The second pattern may be doped with first dopants, which are p-type dopants.

### CROSS-REFERENCE TO RELATED APPLICATIONS

This U.S. non-provisional patent application claims priority under 35 U.S.C. § 119 to Korean Patent Application No. 10-2024-0183537, filed on Dec. 11, 2024, in the Korean Intellectual Property Office, the entire contents of which are hereby incorporated by reference.

### BACKGROUND OF THE INVENTION

The present disclosure relates to a semiconductor device, and in particular, to a semiconductor device including vertical channel transistors and a method of fabricating the same.

As a semiconductor device is scaled down, it is necessary to develop a fabrication technology capable of increasing an integration density, an operation speed, and a production yield of a semiconductor device. Thus, semiconductor devices with vertical channel transistors have been suggested to increase an integration density of a semiconductor device and improve the resistance characteristics and current driving ability of the transistor.

### SUMMARY

Embodiments of the inventive concept provides a semiconductor device with improved electrical and reliability characteristics.

According to some embodiments of the inventive concept, a semiconductor device may include a substrate, a semiconductor pattern on the substrate, a word line, which is on the substrate to be adjacent to the semiconductor pattern and extends in a first direction parallel to a top surface of the substrate, a gate insulating pattern on the substrate and between the semiconductor pattern and the word line, and a bit line that is on the semiconductor pattern and extends in a second direction, which is parallel to the top surface of the substrate and intersects the first direction. The word line may include a first pattern and a second pattern, which is between the first pattern and the gate insulating pattern. The first patterns and the second patterns may include different materials from each other. The second pattern may be doped with first dopants, and the first dopants may be p-type dopants.

According to some embodiments of the inventive concept, a semiconductor device may include a substrate, a semiconductor pattern on the substrate, a word line, which is on the substrate and extends in a first direction parallel to a top surface of the substrate, a gate insulating pattern on the substrate and between the semiconductor pattern and the word line, and a bit line that is on the semiconductor pattern and extends in a second direction, which is parallel to the top surface of the substrate and intersects the first direction. The semiconductor pattern may include a first portion and a second portion, which is on the first portion and is doped with first dopants. The word line may include a first pattern and a second pattern, which is between the first pattern and the gate insulating pattern and is doped with second dopants. The first dopants and the second dopants may be p-type dopants.

According to some embodiments of the inventive concept, a semiconductor device may include a substrate, a data storage pattern on the substrate, a landing pad on the data storage pattern, a semiconductor pattern on the landing pad, a word line, which is on the substrate and extends in a first direction parallel to a top surface of the substrate, a gate insulating pattern on the substrate and between the semiconductor pattern and the word line, a protection pattern on the gate insulating pattern and the word line, and a bit line on the protection pattern and extends in a second direction, which is parallel to the top surface of the substrate and intersects the first direction. The word line may include a first pattern and a second pattern, which is between the first pattern and the gate insulating pattern. The second pattern may be doped with first dopants, and the first dopants may be p-type dopants.

### BRIEF DESCRIPTION OF THE DRAWINGS

FIG. 1 is a block diagram illustrating a semiconductor memory device including a semiconductor device according to some embodiments of the inventive concept.

FIG. 2 is a plan view illustrating a semiconductor device according to some embodiments of the inventive concept.

FIG. 3 is a sectional view taken along line A-A′ of FIG. 2.

FIG. 4 is a sectional view taken along line B-B′ of FIG. 2.

FIG. 5 is an enlarged sectional view illustrating a portion ‘M’ of FIG. 2.

FIGS. 6A, 6B, 7A, 7B, 8A, 8B, 9A, 9B, 10A, 10B, 11A, 11B, 12A, 12B, 13A, 13B, 14A, and 14B are sectional views illustrating a method of fabricating a semiconductor device according to some embodiments of the inventive concept.

### DETAILED DESCRIPTION

Example embodiments of the inventive concepts will now be described more fully with reference to the accompanying drawings, in which example embodiments are shown. Like reference numerals in the drawings denote like elements, and thus their description will be omitted. Herein, the terms indicating order, such as first, second, etc., are used to distinguish elements having the same/similar functions, and the ordinal numbers may be interchanged according to the order in which the terms are mentioned. To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

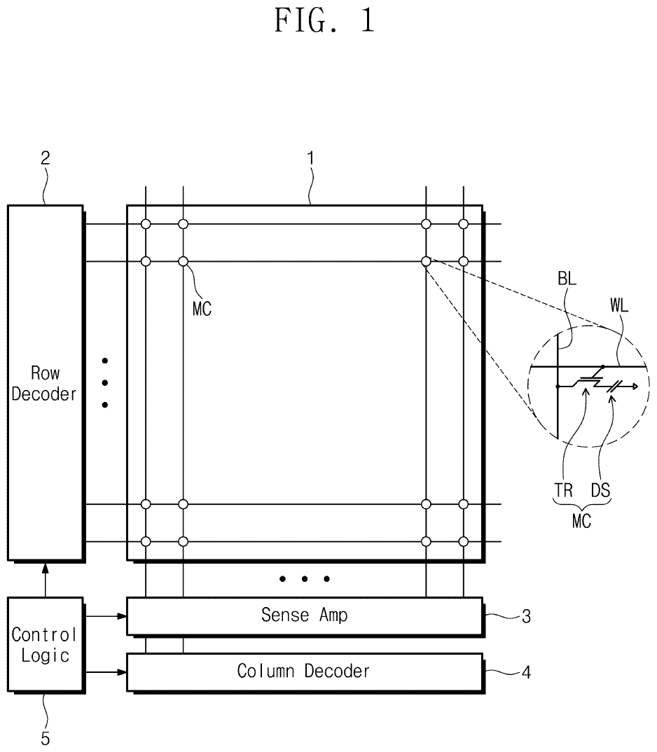

FIG. 1 is a block diagram illustrating a semiconductor memory device including a semiconductor device according to some embodiments of the inventive concept.

Referring to FIG. 1, a semiconductor memory device may include a memory cell array 1, a row decoder 2, a sense amplifier 3, a column decoder 4, and a control logic 5.

The memory cell array 1 may include a plurality of memory cells MC, which are two-dimensionally or three-dimensionally arranged. Each of the memory cells MC may be provided between and connected to a word line WL and a bit line BL, which are disposed to cross each other.

Each of the memory cells MC may include a selection element TR and a data storage device DS, which are electrically connected in series. The data storage device DS may be provided between and connected to the bit line BL and the selection element TR, and the selection element TR may be provided between and connected to the data storage device DS and the word line WL. The selection element TR may be a field effect transistor (FET), and the data storage device DS may be realized using at least one of a capacitor, a magnetic tunnel junction pattern, or a variable resistor. As an example, the selection element TR may include a transistor having a gate electrode, which is connected to the word line WL, and drain/source terminals, which are respectively connected to the bit line BL and the data storage device DS.

The row decoder 2 may be configured to decode address information, which is input from the outside, and to select one of the word lines WL of the memory cell array 1, based on the decoded address information. The address information decoded by the row decoder 2 may be provided to a row driver (not shown), and in this case, the row driver may provide respective voltages to the selected one of the word lines WL and the unselected ones of the word lines WL, in response to the control of a control circuit.

The sense amplifier 3 may be configured to sense, amplify, and output a difference in voltage between one of the bit lines BL, which is selected based on address information decoded by the column decoder 4, and a reference bit line.

The column decoder 4 may provide a data transmission path between the sense amplifier 3 and an external device (e.g., a memory controller). The column decoder 4 may be configured to decode address information, which is input from the outside, and to select one of the bit lines BL, based on the decoded address information.

The control logic 5 may be configured to generate control signals, which are used to control data writing or reading operations on the memory cell array 1.

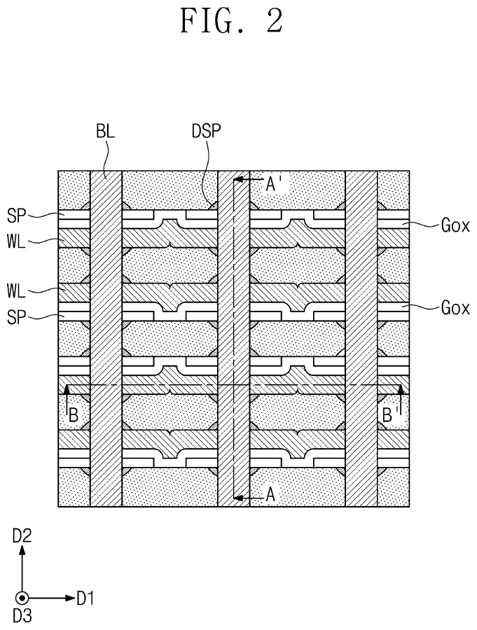

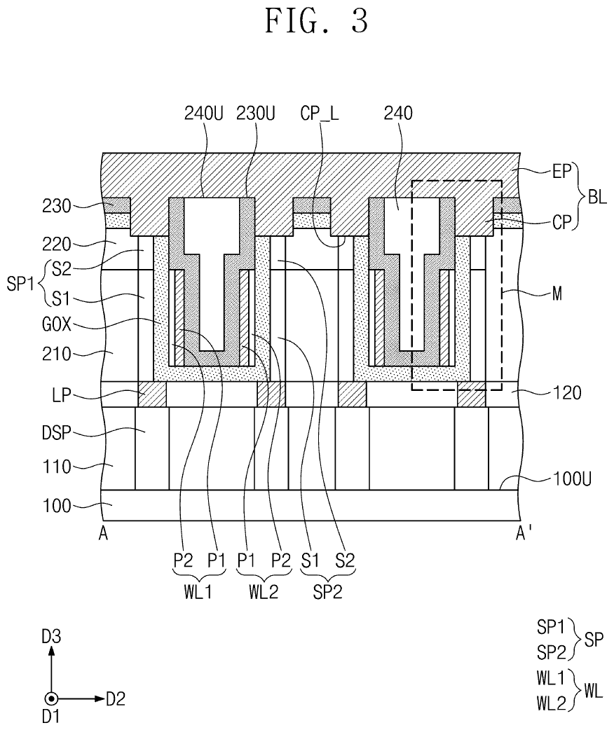

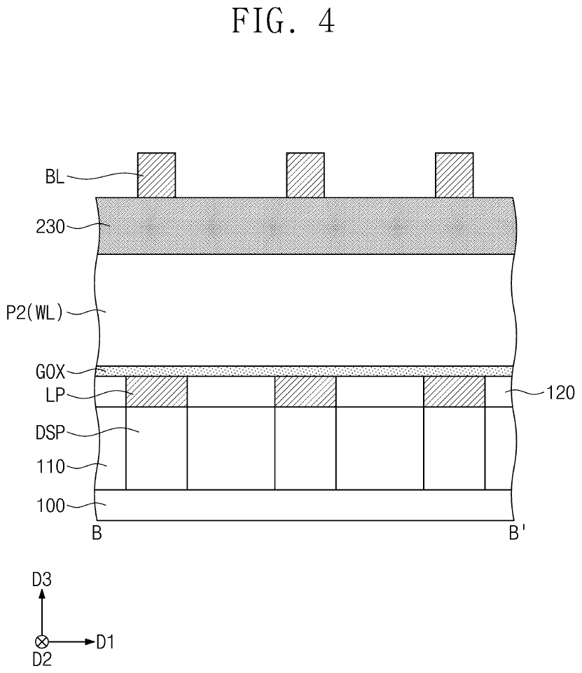

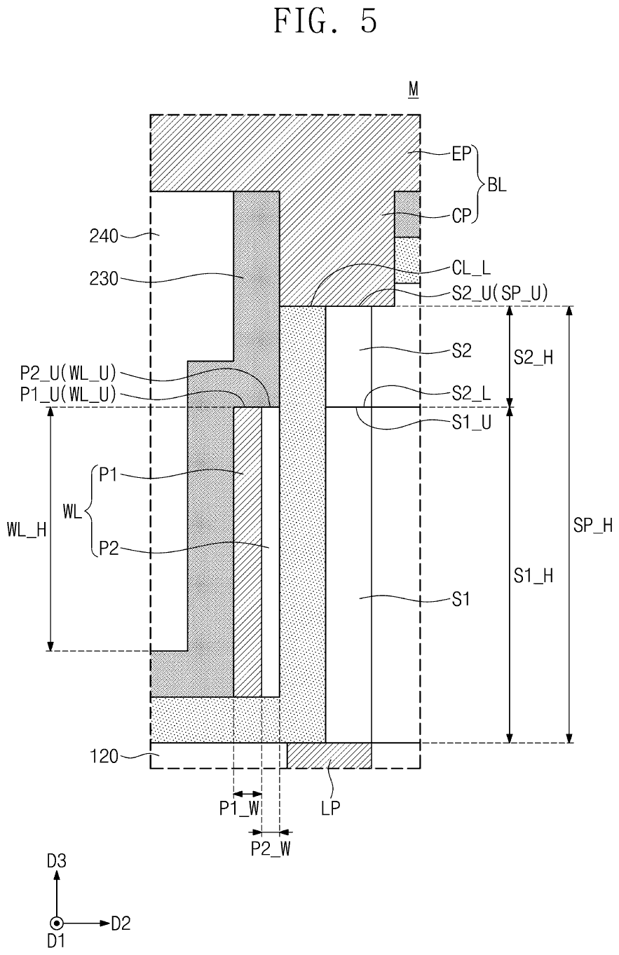

FIG. 2 is a plan view illustrating a semiconductor device according to some embodiments of the inventive concept. FIG. 3 is a sectional view taken along line A-A′ of FIG. 2. FIG. 4 is a sectional view taken along line B-B′ of FIG. 2. FIG. 5 is an enlarged sectional view illustrating a portion ‘M’ of FIG. 2. For concise description, an element described with reference to FIG. 1 may be identified by the same reference number without repeating an overlapping description thereof.

Referring to FIGS. 2 to 5, a substrate 100 may be provided. The substrate 100 may be, for example, a single crystalline silicon substrate. Core and peripheral circuits may be disposed in the substrate 100. The core and peripheral circuits may include the row and column decoders 2 and 4, the sense amplifier 3, and the control logic 5 described with reference to FIG. 1. In some embodiments, the core and peripheral circuits may include NMOS and PMOS transistors integrated on a semiconductor substrate.

A data storage pattern DSP may be disposed on the substrate 100. In some embodiments, the data storage pattern DSP may be a capacitor including bottom and top electrodes and a capacitor dielectric layer interposed therebetween. The top electrode may have various shapes (e.g., circular, elliptical, rectangular, square, diamond, and/or hexagonal shapes), when viewed in a plan view.

In some embodiments, the data storage patterns DSP may be a variable resistance pattern whose resistance can be switched to one of at least two states by an electric pulse applied thereto. For example, the data storage pattern DSP may be formed of or include at least one of phase-change materials whose crystal state can be changed depending on an amount of a current applied thereto, perovskite compounds, transition metal oxides, magnetic materials, ferromagnetic materials, or antiferromagnetic materials.

A first lower insulating layer 110 may be disposed on the substrate 100 to cover or overlap the data storage pattern DSP. In some embodiments, the first lower insulating layer 110 may be formed of or include at least one of silicon nitride, silicon oxide, or silicon oxynitride.

A landing pad LP may be disposed on the data storage pattern DSP. In the case where the data storage pattern DSP is a capacitor, the landing pad LP may be electrically connected to the top electrode of the data storage pattern DSP. The landing pads LP may have various shapes (e.g., circular, elliptical, rectangular, square, diamond, and/or hexagonal shapes), when viewed in a plan view. The landing pad LP may be formed of or include at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but the inventive concept is not limited to these examples.

A second lower insulating layer 120 may be disposed on the first lower insulating layer 110 to fill a region between the landing pads LP. A top surface of the second lower insulating layer 120 may be located at a level higher than a top surface of the landing pad LP. The second lower insulating layer 120 may be formed of or include at least one of silicon nitride, silicon oxide, or silicon oxynitride.

A first interlayer insulating layer 210 may be disposed on the second lower insulating layer 120. A second interlayer insulating layer 220 may be disposed on the first interlayer insulating layer 210. The first interlayer insulating layers 210 and the second interlayer insulating layer 220 may be formed of or include at least one of silicon oxide, silicon nitride, or silicon oxynitride.

A semiconductor pattern SP may be disposed on the landing pad LP and may be disposed in the first interlayer insulating layers 210 and the second interlayer insulating layer 220. In some embodiments, a top surface SP_U of the semiconductor pattern SP may be placed at the same level as a top surface of the second interlayer insulating layer 220. The semiconductor pattern SP may include a first semiconductor pattern SP1 and a second semiconductor pattern SP2, which are opposite to each other in a second direction D2. Each of the first and second semiconductor patterns SP1 and SP2 may be disposed on the landing pad LP.

Each of the first and second semiconductor patterns SP1 and SP2 may include a first portion S1 and a second portion S2 on the first portion S1. A length S1_H of the first portion S1 in a third direction D3 may be larger than or greater than a length S2_H of the second portion S2 in the third direction D3.

In the present specification, a first direction D1 may be parallel to a top surface 100U of the substrate 100. The second direction D2 may be parallel to the top surface 100U of the substrate 100 and may not be parallel to the first direction D1. The third direction D3 may be perpendicular to the top surface 100U of the substrate 100.

Each of the first and second portions S1 and S2 may include an oxide semiconductor material. For example, the oxide semiconductor material may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or combinations thereof. In some embodiments, the semiconductor pattern SP may include indium gallium zinc oxide (IGZO). The semiconductor pattern SP may have a single- or multi-layered structure that is made of the oxide semiconductor material. The semiconductor pattern SP may include an amorphous, crystalline, or polycrystalline oxide semiconductor material. For example, the semiconductor patterns SP may have a polycrystalline or amorphous structure, but the inventive concept is not limited to this example. In some embodiments, the semiconductor pattern SP may include at least one of two-dimensional semiconductor materials (e.g., graphene, carbon nanotube, or combinations thereof).

The second portion S2 may be doped with first dopants. In some embodiments, the first dopants may be p-type dopants and may include at least one selected from the group consisting of boron, aluminum, gallium, and/or indium. The concentration of the first dopants in the first portion S1 may be lower than the concentration of the first dopants in the second portion S2. In some embodiments, the concentration of the first dopants in the first portion S1 may be 0.01% to 1% of the concentration of the first dopants in the second portion S2. The first portion S1 may not include the first dopants.

In some embodiments, the semiconductor pattern SP may include the second portion S2 doped with p-type dopants. The density of oxygen vacancy in the semiconductor pattern SP may be increased, and therefore, the resistance of the semiconductor pattern may be lowered. Thus, the semiconductor device with improved electrical characteristics may be provided.

The word line WL may be extended in the first direction D1, on the substrate 100, and may be disposed to be adjacent to the semiconductor pattern SP. The word line WL may include a first word line WL1 and a second word line WL2, which are placed to be adjacent to the first semiconductor pattern SP1 and the second semiconductor pattern SP2, respectively. The first word line WL1 and the second word line WL2 may be opposite to each other in the second direction D2. The semiconductor pattern SP may be controlled by the word line WL.

A top surface WL_U of the word line WL may be located at a level lower than the top surface SP_U of the semiconductor pattern SP. The top surface WL_U of the word line WL may be located at a level lower than a top surface S2_U of the second portion S2 of the semiconductor pattern SP. The top surface WL_U of the word line WL may be located at a level that is equal to or lower than a top surface S1_U of the first portion S1 of the semiconductor pattern SP. The top surface WL_U of the word line WL may be located at a level that is equal to or lower than a bottom surface S2_L of the second portion S2 of the semiconductor pattern SP. A length WL_H of the word line WL in the third direction D3 may be smaller than or less than a length SP_H of the semiconductor pattern SP in the third direction D3. The length WL_H of the word line WL in the third direction D3 may be equal to or smaller than or less than the length S1_H of the first portion S1 of the semiconductor pattern SP in the third direction D3.

Each of the first and second word lines WL1 and WL2 may include a first pattern P1 and a second pattern P2, which is disposed between the first pattern P1 and the semiconductor pattern SP. A top surface P1_U of the first pattern P1 and a top surface P2_U of the second pattern P2 may be placed at the same level. The top surface P2_U of the second pattern P2 may be placed at a level that is equal to or lower than the top surface S1_U of the first portion S1 of the semiconductor pattern SP. The top surface P2_U of the second pattern P2 may be disposed at a level, which is equal to or lower than the bottom surface S2_L of the second portion S2 of the semiconductor pattern SP. The levels and/or heights described herein may be measured, for example, with respect to the substrate 100.

A length of the first pattern P1 in the third direction D3 may be equal to a length of the second pattern P2 in the third direction D3. A width P1_W of the first pattern P1 in the second direction D2 may be larger than or greater than a width P2_W of the second pattern P2 in the second direction D2.

The first pattern P1 may be formed of or include at least one of metallic materials. The metallic materials may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but the inventive concept is not limited to these examples.

The second pattern P2 may include a material different from the first pattern P1. The second pattern P2 may include poly silicon that is doped with second dopants. The second dopants may be p-type dopants and may include at least one selected from the group consisting of boron, aluminum, gallium, and indium. The first and second dopants may have the same conductivity type. The first and second dopants may include the same material.

In some embodiments, the second pattern P2 of the word line WL may be formed of or include poly silicon that is doped with p-type dopants. Thus, a threshold voltage (Vth) of the semiconductor device may be increased.

A gate insulating pattern GOX may be interposed between the semiconductor pattern SP and the word line WL. In detail, the gate insulating pattern GOX may be interposed between the semiconductor pattern SP and the second pattern P2 of the word line WL. The gate insulating pattern GOX may extend into regions between the semiconductor pattern SP and the second pattern P2 of the word line WL and between the word line WL and the second lower insulating layer 120. The gate insulating pattern GOX may extend to a region on the second portion S2 of the semiconductor pattern SP in the third direction D3. The gate insulating pattern GOX may be formed of or include at least one of silicon oxide, silicon oxynitride, high-k dielectric materials having dielectric constants higher than silicon oxide, or combinations thereof. The high-k dielectric material may be formed of at least one of metal oxide materials or metal oxynitride materials. For example, the high-k dielectric materials for the gate insulating pattern GOX may include HfO2, HfSiO, HfSiON, HfTaO, HfTiO, HfZrO, ZrO2, Al₂O₃, or combinations thereof, but the inventive concept is not limited to these examples.

A protection pattern 230 may be disposed on the gate insulating pattern GOX. The protection pattern 230 may cover a top surface of the second pattern P2 of the word line WL and top and side surfaces of the first pattern P1 of the word line WL. In some embodiments, the protection pattern 230 may be formed of or include at least one of silicon nitride or silicon oxynitride. The gate insulating pattern GOX may extend into a region between the second portion S2 of the semiconductor pattern SP and the protection pattern 230.

A third interlayer insulating layer 240 may partially or completely fill a region between adjacent portions of the protection patterns 230. A top surface 240U of the third interlayer insulating layer 240 may be coplanar with a top surface 230U of the protection pattern 230. The gate insulating pattern GOX and the protection pattern 230 may extend into a region between the second lower insulating layer 120 and the third interlayer insulating layer 240. The third interlayer insulating layer 240 may be formed of or include at least one of silicon oxide or silicon oxynitride.

The bit line BL may be disposed on the third interlayer insulating layer 240 and the protection pattern 230 and may extend in the second direction D2. The bit line BL may be disposed on and be electrically connected to the semiconductor pattern SP.

The bit line BL may include an extended portion EP, which is provided on the third interlayer insulating layer 240 and the protection pattern 230 and is extended in the second direction D2, and a connecting portion CP, which extends from the extended portion EP and protrudes toward the substrate 100. The connecting portion CP may be provided the semiconductor pattern SP to penetrate or extend into the third interlayer insulating layer 240 and/or the protection pattern 230. The bottommost surface CP_L of the connecting portion CP may be referred to as the bottommost surface of the bit line BL.

The bottommost surface CP_L of the connecting portion CP may be in contact with the top surface SP_U of the semiconductor pattern SP. In detail, the top surface S2_U of the second portion S2 of the semiconductor pattern SP may be in contact with the bottommost surface CP_L of the connecting portion CP.

The bottommost surface CP_L of the connecting portion CP may be spaced apart from the word line WL in a vertical direction (e.g., in the third direction D3). The bottommost surface CP_L of the connecting portion CP may be located at a level higher than the topmost surface WL_U of the word line WL. That is, the bit line BL may not be overlapped with the word line WL in a horizontal direction (e.g., in the first and second directions D1 and D2).

In some embodiments, since the bit line BL and the word line WL are not overlapped with each other in the horizontal direction, it may be possible to reduce a short circuit issue from occurring between the bit line BL and the word line WL. Accordingly, a semiconductor device with improved reliability may be provided.

In some embodiments, the bit line BL may be formed of or include at least one of doped polysilicon, metallic materials, conductive metal nitride materials, conductive metal silicide materials, conductive metal oxide materials, or combinations thereof. The bit lines BL may be formed of or include at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but the inventive concept is not limited to these examples. The bit lines BL may have a single-layered or multi-layered structure that is made of at least one of the afore-described materials. In some embodiments, the bit lines BL may include a two-dimensional semiconductor material (e.g., graphene, carbon nanotube, or combinations thereof).

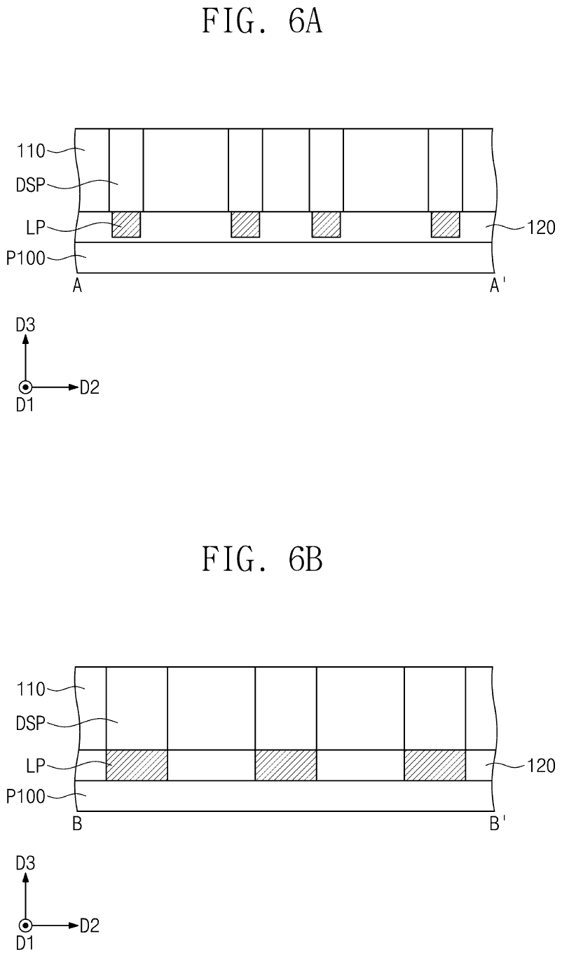

FIGS. 6A, 6B, 7A, 7B, 8A, 8B, 9A, 9B, 10A, 10B, 11A, 11B, 12A, 12B, 13A, 13B, 14A, and 14B are sectional views illustrating a method of fabricating a semiconductor device according to some embodiments of the inventive concept. FIGS. 6A, 7A, 8A, 9A, 10A, 11A, 12A, 13A, and 14A are sectional views taken along a line A-A′ of FIG. 2. FIGS. 6B, 7B, 8B, 9B, 10B, 11B, 12B, 13B, and 14B are sectional views taken along a line B-B′ of FIG. 2. For concise description, an element described with reference to FIGS. 1 to 5 may be identified by the same reference number without repeating an overlapping description thereof.

Referring to FIGS. 6A and 6B, the landing pad LP may be formed on a preliminary substrate P100, and the data storage pattern DSP may be formed on the landing pad LP. In some embodiments, the formation of the landing pad LP may include depositing the second lower insulating layer 120 on the preliminary substrate P100, forming a mask pattern on the second lower insulating layer 120, etching the second lower insulating layer 120 using the mask pattern as an etch mask to form empty regions, and partially or completely filling the empty regions in the second lower insulating layer 120 with a conductive material. The data storage pattern DSP may be formed on the landing pad LP, and the first lower insulating layer 110 may be formed to cover or overlap the data storage pattern DSP.

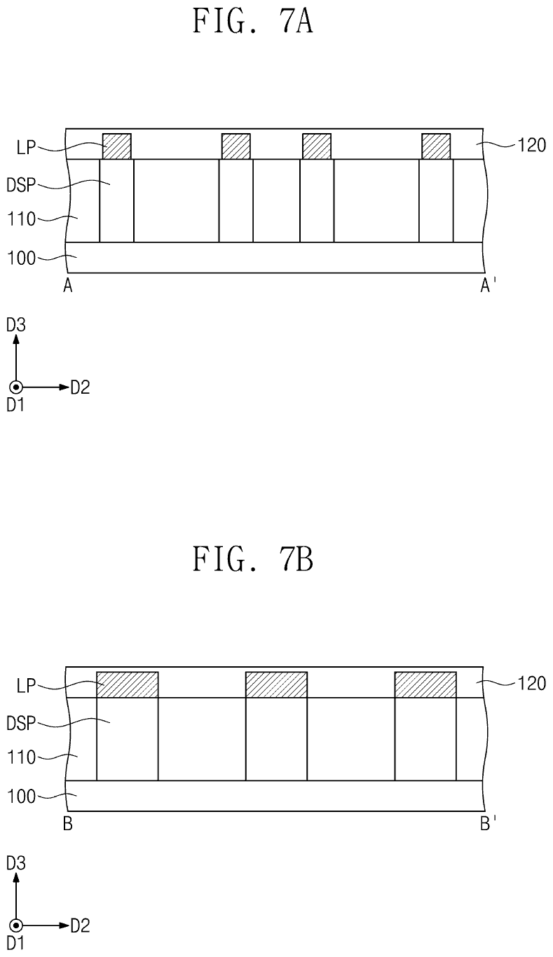

Referring to FIGS. 7A and 7B, the substrate 100 may be provided on the data storage pattern DSP. The substrate 100 may be inverted in such a way that the substrate 100, the data storage pattern DSP, and the landing pad LP are stacked sequentially in the specified order. Next, the preliminary substrate P100 may be removed.

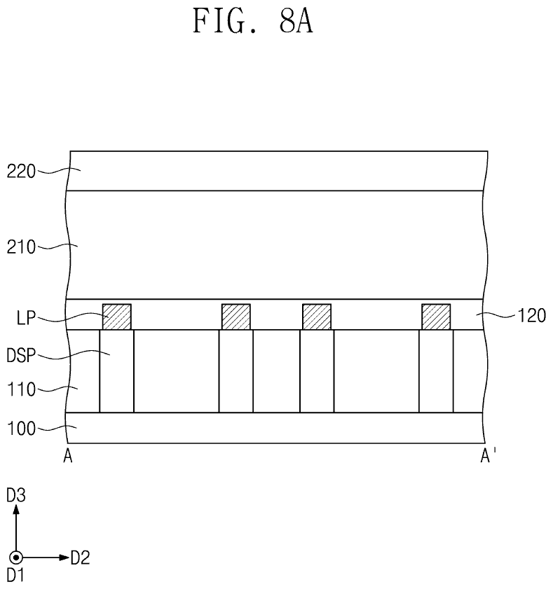

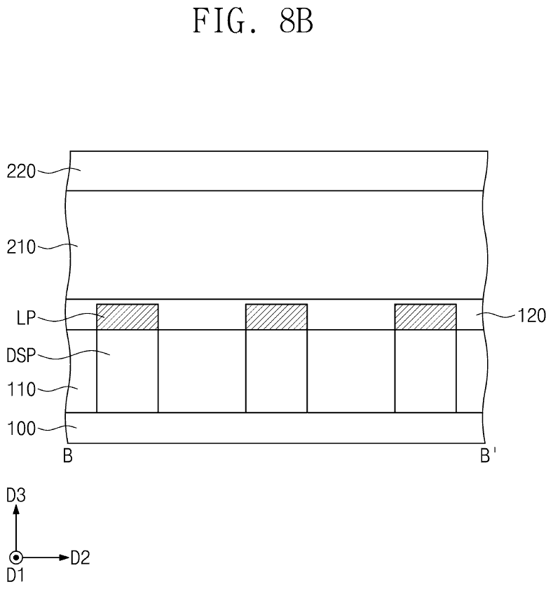

Referring to FIGS. 8A and 8B, the first interlayer insulating layer 210 may be deposited on the second lower insulating layer 120. The second interlayer insulating layer 220 may be deposited on the first interlayer insulating layer 210. The formation of the first interlayer insulating layers 210 and the second interlayer insulating layer 220 may include performing a physical vapor deposition process or a chemical vapor deposition process.

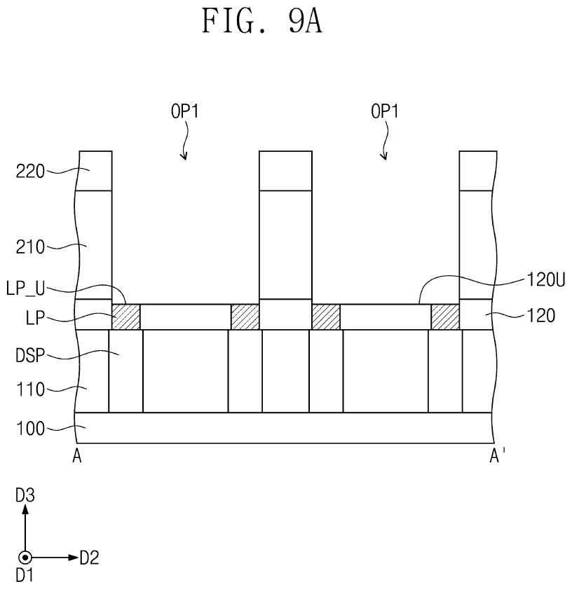

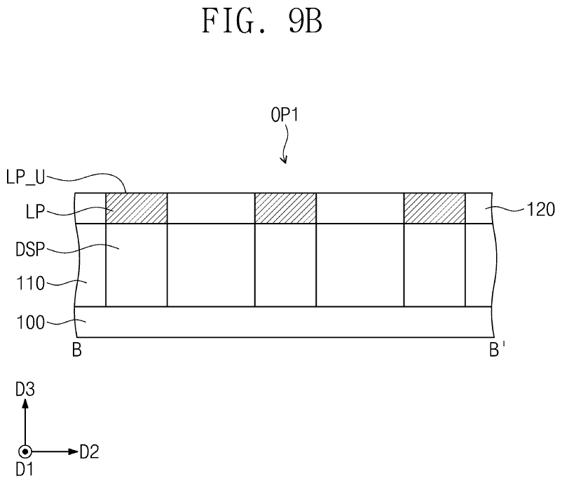

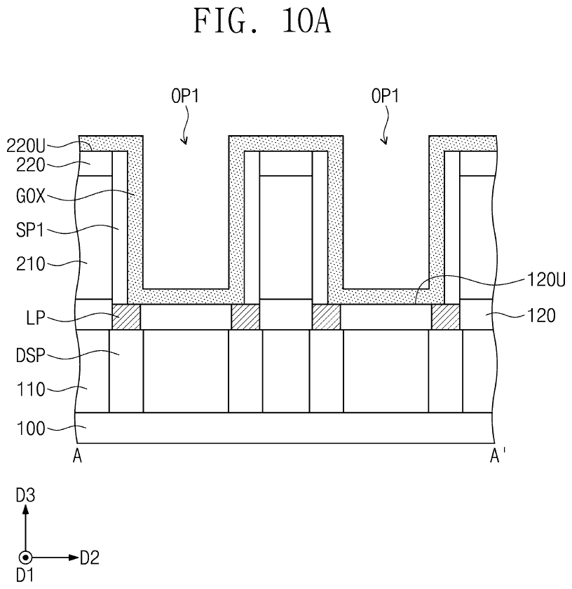

Referring to FIGS. 9A and 9B, a first hole OP1 may be formed to penetrate or extend into the first interlayer insulating layers 210 and the second interlayer insulating layer 220. The first hole OP1 may be formed to expose a top surface LP_U of the landing pad LP and a top surface 120U of the second lower insulating layer 120. In some embodiments, the formation of the first hole OP1 may include forming a mask pattern on the second interlayer insulating layer 220 and etching the first interlayer insulating layer 210 and second interlayer insulating layer 220 using the mask pattern as an etch mask.

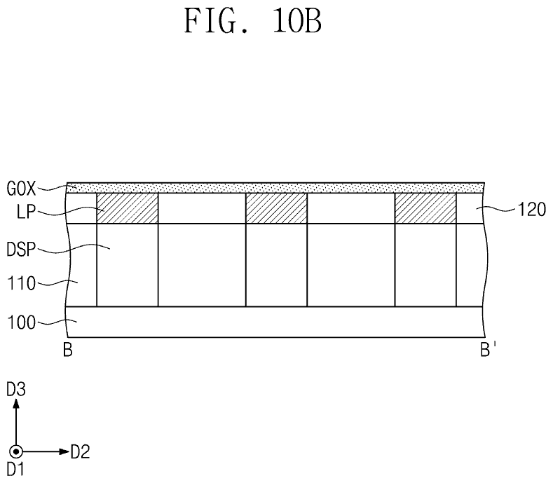

Referring to FIGS. 10A and 10B, the first and second semiconductor patterns SP1 and SP2 may be formed in the first hole OP1. Each of the first and second semiconductor patterns SP1 and SP2 may be formed on the landing pad LP exposed by the first hole OP1.

In some embodiments, the formation of the first and second semiconductor patterns SP1 and SP2 may include depositing a semiconductor oxide layer to cover or overlap a top surface 220U of the second interlayer insulating layer 220 and an inner surface of the first hole OP1 and removing the semiconductor oxide layer from the top surface 220U of the second interlayer insulating layer 220 and the top surface 120U of the second lower insulating layer 120. The removal process may be performed to expose the second interlayer insulating layer 220 and the top surface 120U of the second lower insulating layer 120. In some embodiments, the removal process may be an etch-back process.

In some embodiments, the first and second semiconductor patterns SP1 and SP2 may be disposed on the data storage pattern DSP and the landing pad LP. In this case, it may be possible to prevent the first and second semiconductor patterns SP1 and SP2 from being deteriorated by the process of forming the data storage pattern DSP and the landing pad LP. Accordingly, a semiconductor device with improved reliability may be provided.

The gate insulating pattern GOX may be deposited on the top surface 220U of the second interlayer insulating layer 220 and the top surface 120U of the second lower insulating layer 120. The gate insulating pattern GOX may cover or overlap the first and second semiconductor patterns SP1 and SP2. In some embodiments, the gate insulating pattern GOX may be formed by a physical vapor deposition method or a chemical vapor deposition method.

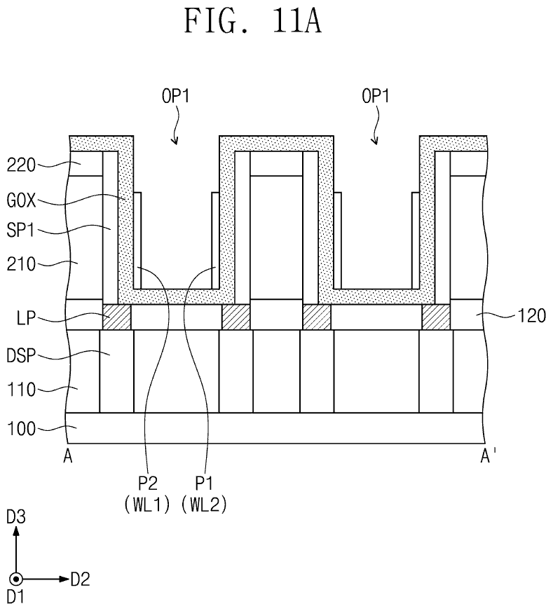

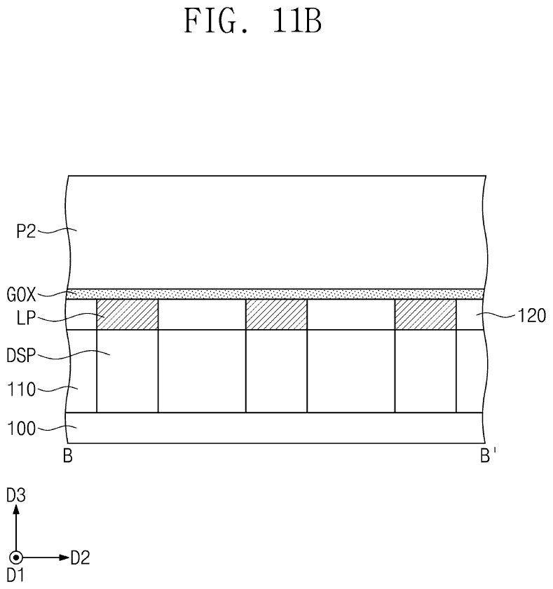

Referring to FIGS. 11A and 11B, the second pattern P2 of the word line WL may be formed on the gate insulating pattern GOX. The second pattern P2 of the first word line WL1 may be formed to be adjacent to the first semiconductor pattern SP1. The second pattern P2 of the second word line WL2 may be formed to be adjacent to the second semiconductor pattern SP2.

In some embodiments, the formation of the second pattern P2 may include depositing a poly-silicon layer on the gate insulating pattern GOX and patterning the poly-silicon layer.

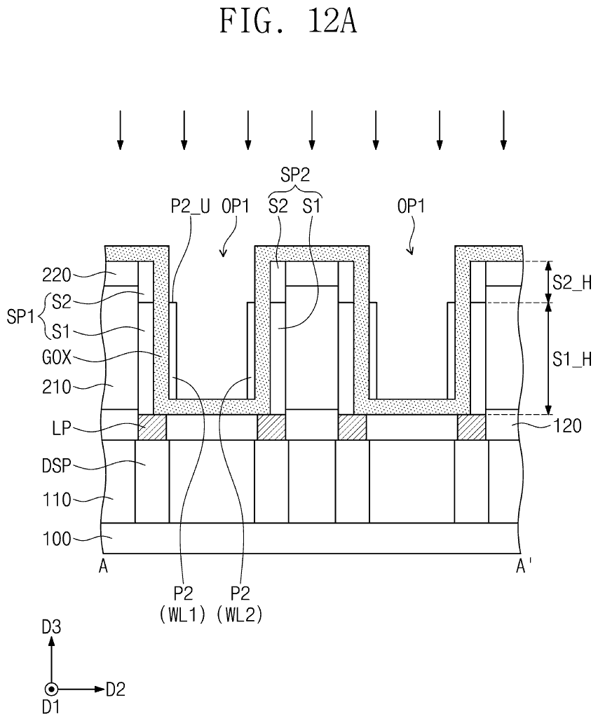

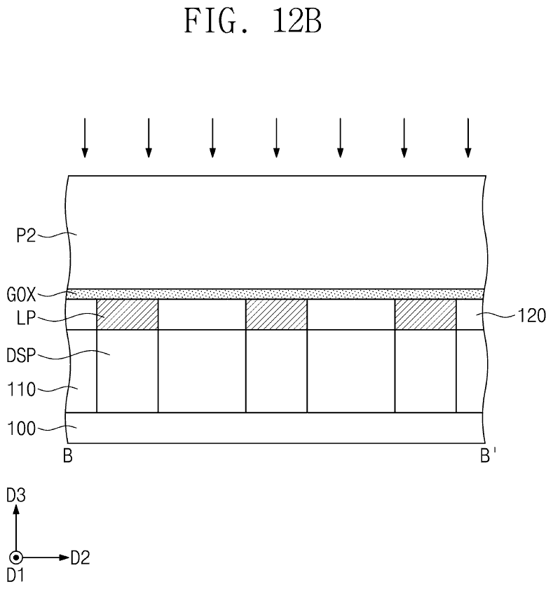

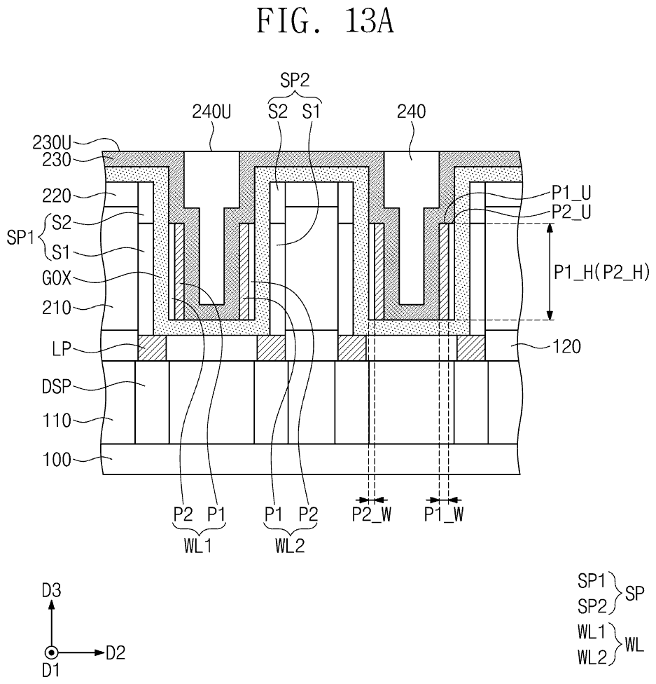

Referring to FIGS. 12A and 12B, a doping process may be performed. The doping process may include doping the first and second semiconductor patterns SP1 and SP2 with first dopants and doping the second pattern P2 of the word line with second dopants. The doping of the first and second semiconductor patterns SP1 and SP2 and the word line WL may be performed at the same time. The first and second dopants may be the same dopants. In some embodiments, the first and second dopants may be p-type dopants (e.g., at least one selected from the group consisting of boron, aluminum, gallium, and/or indium).

As a result of the doping process, the first portion S1 and the second portion S2 on the first portion S1 may be formed for each of the first and second semiconductor patterns SP1 and SP2. The length S1_H of the first portion S1 in the third direction D3 may be larger than or greater than the length S2_H of the second portion S2 in the third direction D3. The second portion S2 may be doped with the first dopants. The first portion S1 may not include the first dopants.

The first portion S1 may be protected by the second portion S2 and the second pattern P2 of the word line WL, and thus, the first portion S1 may not be doped with the first dopants. Thus, the top surface S1_U of the first portion S1 may be at a level that is equal to or higher than the top surface P2_U of the second pattern P2 of the word line WL. The bottom surface S2_L of the second portion S2 may be at a level that is equal to or higher than the top surface P2_U of the second pattern P2 of the word line WL. The referenced levels may be a height measured with respect to the substrate 100.

In some embodiments, the semiconductor pattern SP may include the second pattern P2 doped with p-type dopants. The density of oxygen vacancy in the semiconductor pattern SP may be increased, and thus, the resistance of the semiconductor pattern SP may be lowered. Thus, the semiconductor device with improved electrical characteristics may be provided.

Furthermore, the second pattern P2 of the word line WL may include poly silicon that is doped with p-type dopants. Thus, the threshold voltage (Vth) of the semiconductor device may be increased.

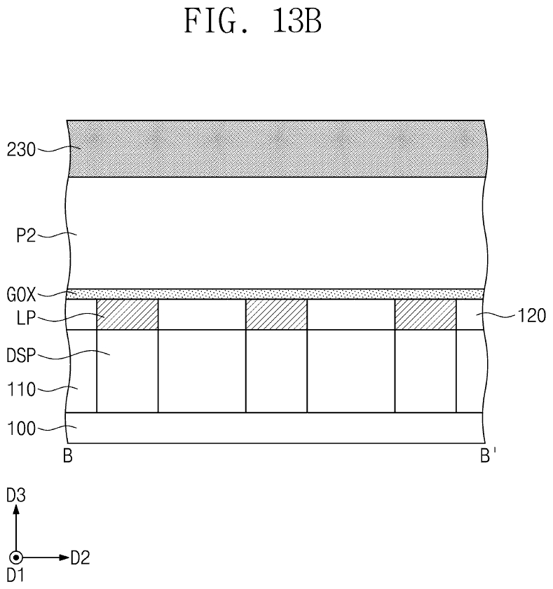

Referring to FIGS. 13A and 13B, the first pattern P1 of the word line WL may be formed on the gate insulating pattern GOX. The first pattern P1 of the first word line WL1 may be formed to be adjacent to the first semiconductor pattern SP1. The first pattern P1 of the second word line WL2 may be formed to be adjacent to the second semiconductor pattern SP2.

The top surface P1_U of the first pattern P1 may be located at the same level as the top surface P2_U of the second pattern P2. A length P1_H of the first pattern P1 in the third direction D3 may be equal to a length P2_H of the second pattern P2 in the third direction D3. The width P1_W of the first pattern P1 in the second direction D2 may be larger than or greater than the width P2_W of the second pattern P2 in the second direction D2. In some embodiments, the formation of the first pattern P1 may include depositing a metal layer on the gate insulating pattern GOX and patterning the metal layer.

The protection pattern 230 may be formed on the gate insulating pattern GOX. The protection pattern 230 may cover or overlap the first and second patterns P1 and P2 of the word line WL. The third interlayer insulating layer 240 may be formed on the protection pattern 230. In some embodiments, the formation of the third interlayer insulating layer 240 may include forming an insulating material on the protection pattern 230 and planarizing the insulating material to expose a top surface of the protection pattern 230. As a result of the planarization process, the top surface 230U of the protection pattern 230 and the top surface 240U of the third interlayer insulating layer 240 may be placed at the same level.

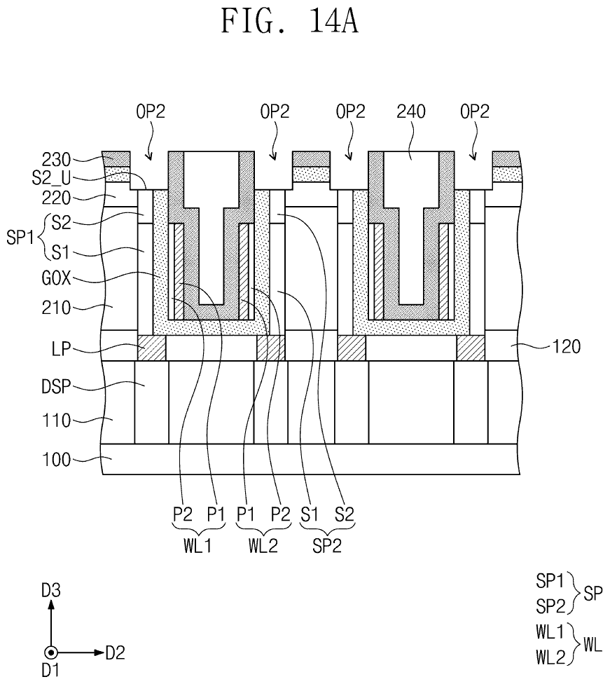

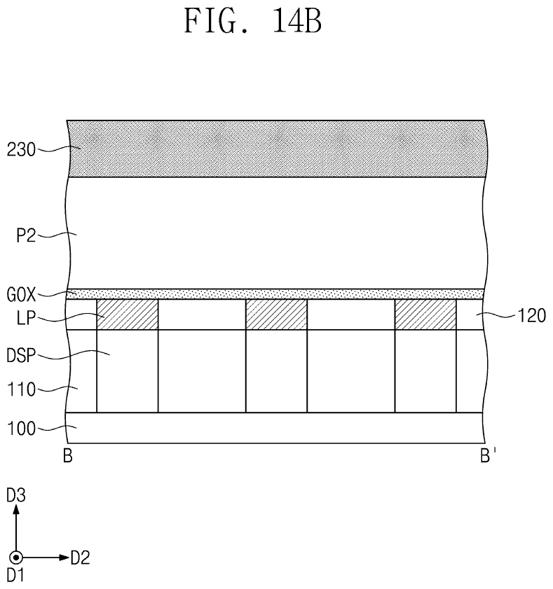

Referring to FIGS. 14A and 14B, a second hole OP2 may be formed to penetrate or extend into the protection pattern 230 and the gate insulating pattern GOX. The second hole OP2 may expose top surfaces of the first and second semiconductor patterns SP1 and SP2. The second hole OP2 may be formed to expose the top surface S2_U of the second portion S2 of the first or second semiconductor pattern SP1 or SP2. A bottom surface of the second hole OP2 may be formed at a level higher than the top surface of the word line WL. The second hole OP2 may not be overlapped with the word line WL in a horizontal direction.

In some embodiments, the formation of the second hole OP2 may include forming a mask pattern on the protection pattern 230 and etching the protection pattern 230 and the gate insulating pattern GOX using the mask pattern as an etch mask.

Referring back to FIGS. 2 to 5, the bit line BL may be formed on the protection pattern 230. The bit line BL may be extended in the second direction D2. The bit line BL may include the extended portion EP, which is provided on the third interlayer insulating layer 240 and the protection pattern 230 and extends in the second direction D2, and the connecting portion CP, which extends from the extended portion EP and protrudes toward the substrate 100.

In some embodiments, the formation of the bit line BL may include depositing a metallic material on the second hole OP2 and the protection pattern 230. Here, the metallic material partially or completely filling the second hole OP2 may be referred to as the connecting portion CP, and the metallic material, which is provided on a top surface of the protection pattern 230 and is extended in the second direction D2, may be referred to as the extended portion EP.

The bottommost surface CP_L of the connecting portion CP may be referred to as the bottommost surface of the bit line BL. The bottommost surface CP_L of the connecting portion CP may be in contact with the top surface SP_U of the semiconductor pattern SP. In detail, the top surface S2_U of the second portion S2 of the semiconductor pattern SP and the bottommost surface CP_L of the connecting portion CP may be in contact with each other.

The bottommost surface CP_L of the connecting portion CP may be spaced apart from the word line WL vertically (e.g., in the third direction D3). The bottommost surface CP_L of the connecting portion CP may be located at a level higher than the topmost surface WL_U of the word line WL. That is, the bit line BL may not be overlapped with the word line WL in a horizontal direction (e.g., in the first and second directions D1 and D2).

In some embodiments, since the bit line BL and the word line WL are not overlapped with each other in the horizontal direction, it may be possible to reduce a short circuit issue between the bit line BL and the word line WL. Accordingly, it may be possible to improve the reliability of the semiconductor device.

According to some embodiments of the inventive concept, a semiconductor pattern and a word line may be doped with p-type dopants. Thus, the resistance of the semiconductor pattern may be lowered, and this may make it possible to improve the electrical characteristics of the semiconductor device. In addition, a word line may be doped with p-type dopants, and in this case, the semiconductor device may have improved electrical characteristics (e.g., threshold voltage (Vth)).

Furthermore, the word line may not be overlapped with a bit line in a horizontal direction. Thus, it may be possible to prevent a short circuit issue from occurring between the word line and the bit line. That is, the semiconductor device may be provided to have improved reliability.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a substrate;
a semiconductor pattern on the substrate;
a word line which is on the substrate and extends in a first direction parallel to a top surface of the substrate;
a gate insulating pattern on the substrate and between the semiconductor pattern and the word line; and
a bit line that is on the semiconductor pattern and extends in a second direction, which is parallel to the top surface of the substrate and intersects the first direction,
wherein the word line comprises:
a first pattern; and
a second pattern between the first pattern and the gate insulating pattern,
wherein the first pattern and the second pattern comprise different materials from each other,
wherein the second pattern is doped with first dopants, and
wherein the first dopants comprise p-type dopants.

2. The semiconductor device of claim 1, wherein a width of the second pattern in the second direction is less than a width of the first pattern in the second direction.

3. The semiconductor device of claim 1, wherein the first pattern comprises a metallic material, and
wherein the second pattern comprises poly silicon doped with the first dopants.

4. The semiconductor device of claim 1, wherein the first dopants are at least one material selected from the group consisting of boron, aluminum, gallium, and indium.

5. The semiconductor device of claim 1, wherein a length of the semiconductor pattern in a third direction is greater than a length of the word line in the third direction, and
wherein the third direction is perpendicular to the top surface of the substrate.

6. The semiconductor device of claim 1, wherein the semiconductor pattern comprises:
a first portion; and
a second portion on the first portion,
wherein a length of the second portion in a third direction is less than a length of the first portion in the third direction, and
wherein the third direction is perpendicular to the top surface of the substrate.

7. The semiconductor device of claim 6, wherein the second portion is doped with second dopants, and
wherein the second dopants comprise p-type dopants.

8. The semiconductor device of claim 1, wherein a distance from a bottommost surface of the bit line to the substrate is greater than a distance from a topmost surface of the word line to the substrate.

9. The semiconductor device of claim 1, wherein the semiconductor pattern comprises:
a first portion; and
a second portion on the first portion,
wherein a distance from a top surface of the first portion of the semiconductor pattern to the substrate is equal to or greater than a distance from a top surface of the second pattern of the word line to the substrate.

10. The semiconductor device of claim 1, wherein the semiconductor pattern comprises:
a first portion; and
a second portion on the first portion,
wherein a distance from a top surface of the second portion of the semiconductor pattern to the substrate is greater than a distance from a top surface of the word line to the substrate.

11. The semiconductor device of claim 1, further comprising:
a data storage pattern on the substrate; and
a landing pad on the data storage pattern,
wherein the semiconductor pattern is on the landing pad.

12. A semiconductor device, comprising:
a substrate;
a semiconductor pattern on the substrate;
a word line, which is on the substrate and extends in a first direction parallel to a top surface of the substrate;
a gate insulating pattern on the substrate and between the semiconductor pattern and the word line; and
a bit line that is on the semiconductor pattern and extends in a second direction, which is parallel to the top surface of the substrate and intersects the first direction,
wherein the semiconductor pattern comprises:
a first portion; and
a second portion on the first portion and doped with first dopants,
wherein the word line comprises:
a first pattern; and
a second pattern between the first pattern and the gate insulating pattern and doped with second dopants,
wherein the first dopants and the second dopants comprise p-type dopants.

13. The semiconductor device of claim 12, wherein the first portion and the second portion of the semiconductor pattern comprise semiconductor oxide.

14. The semiconductor device of claim 12, wherein the semiconductor pattern is selected from the group consisting of IGZO, InₓO, ZnₓO, SnₓO, InₓZn_{y}O, InₓSn_{y}ZnzO, AlₓZn_{y}Sn_{z}O, YbₓGa_{y}ZnzO, HfₓIn_{y}Zn_{z}O, and combinations thereof.

15. The semiconductor device of claim 12, wherein each of the first dopants and the second dopants are at least one selected from the group consisting of boron, aluminum, gallium, and indium.

16. The semiconductor device of claim 12, wherein the first pattern of the word line comprises a metallic material, and
wherein the second pattern of the word line comprises poly silicon doped with the second dopants.

17. The semiconductor device of claim 12, wherein a distance from a bottommost surface of the bit line to the substrate is greater than a distance from a top surface of the word line to the substrate.

18. A semiconductor device, comprising:
a substrate;
a data storage pattern on the substrate;
a landing pad on the data storage pattern;
a semiconductor pattern on the landing pad;
a word line which is on the substrate and extends in a first direction parallel to a top surface of the substrate;
a gate insulating pattern on the substrate and between the semiconductor pattern and the word line;
a protection pattern on the gate insulating pattern and the word line; and
a bit line on the protection pattern and extends in a second direction which is parallel to the top surface of the substrate and intersects the first direction,
wherein the word line comprises:
a first pattern; and
a second pattern between the first pattern and the gate insulating pattern,
wherein the second pattern is doped with first dopants, and
wherein the first dopants comprise p-type dopants.

19. The semiconductor device of claim 18, wherein the semiconductor pattern comprises:
a first portion; and
a second portion on the first portion,
wherein the second portion is doped with second dopants, and
wherein the first dopants and the second dopants comprise a same material.

20. The semiconductor device of claim 18, wherein a distance from a bottommost surface of the bit line to the substrate is greater than a distance from a topmost surface of the word line to the substrate.
